(19) United States
(12) Patent Application Publication
(10) Pub. No.: US 2023/0422411 A1
(43) Pub. Date: Dec. 28, 2023

(54) SUBSTRATE STRUCTURE

(71) Applicant: Subtron Technology Co., Ltd., Hsinchu County (TW)

(72) Inventor: Chung Ying Lu, Hsinchu County (TW)

(73) Assignee: Subtron Technology Co., Ltd., Hsinchu County (TW)

(21) Appl. No.: 17/899,625

(22) Filed: Aug. 31, 2022

(30) Foreign Application Priority Data
Jun. 24, 2022 (TW) 111123741

(51) Int. Cl. H05K 3/46; H05K 1/05; H05K 3/00

(52) U.S. Cl. CPC H05K 3/4644; H05K 1/056; H05K 3/0035; H05K 2203/0323; H05K 2201/0959

(57) ABSTRACT

A substrate structure includes a metal substrate, an insulating material, at least one first dielectric layer, and at least one first patterned circuit layer. The metal substrate has a first surface and a second surface opposite to each other and multiple through holes penetrating the metal substrate and connecting the first surface and the second surface. The insulating material fills the through holes and is aligned with the first surface and the second surface. The first dielectric layer is disposed on the first surface and the insulating material, and has multiple first openings. The first openings partially expose the metal substrate. The material of the first dielectric layer includes aluminum nitride or silicon carbide. The first patterned circuit layer is disposed on the first dielectric layer, fills the first openings, and connected to the metal substrate. The first patterned circuit layer partially exposes the first dielectric layer.

### CROSS-REFERENCE TO RELATED APPLICATION

This application claims the priority benefit of Taiwan application serial no. 111123741, filed on Jun. 24, 2022. The entirety of the above-mentioned patent application is hereby incorporated by reference herein and made a part of this specification.

### BACKGROUND

### Technical Field

The present disclosure relates to a substrate structure, particularly to a thin, lightweight substrate structure.

### Description of Related Art

It is the current technique to form a package substrate by using the organic resin impregnated fiberglass cloth as the core board, adding thereto a pure resin material (such as an ABF) or a resin impregnated fiberglass cloth (also known as prepreg) as the build-up material, then forming holes by mechanically or laser drilling the core layer and laser drilling the build-up material, and forming a via structure by electroplating a metal layer in the holes. However, as the thickness of the build-up material is about 25 μm or more, and the thickness of the core layer is also much greater than that of the build-up material, the package substrate does not meet the current trend of thinner package.

### SUMMARY

The disclosure provides a thin, lightweight substrate structure.

The substrate structure of the disclosure includes a metal substrate, an insulating material, at least one first dielectric layer, and at least one first patterned circuit layer. The metal substrate has a first surface and a second surface opposite to each other and a plurality of through holes penetrating the metal substrate and connecting the first surface and the second surface. The insulating material fills the through holes and is aligned with the first surface and the second surface. The first dielectric layer is disposed on the first surface of the metal substrate and the insulating material and has a plurality of first openings. The first openings partially expose the metal substrate, and the material of the first dielectric layer includes aluminum nitride (AlN) or silicon carbide (SiC). The first patterned circuit layer is disposed on the first dielectric layer and is configured to fill the first opening and be connected to the metal substrate. The first patterned circuit layer partially exposes the first dielectric layer.

In an embodiment of the disclosure, the substrate structure further includes a solder mask layer disposed on the first patterned circuit layer. The solder mask layer has a plurality of solder mask openings, and the solder mask openings partially expose the first patterned circuit layer.

In an embodiment of the disclosure, the substrate structure further includes at least one second dielectric layer. The second dielectric layer is disposed on the second surface of the metal substrate and the insulating material. The second dielectric layer has a plurality of second openings, and the second openings partially expose the metal substrate. The material of the second dielectric layer includes aluminum nitride or silicon carbide.

In an embodiment of the disclosure, the substrate structure further includes at least one second patterned circuit layer disposed on the second dielectric layer and configured to fill the second openings and be connected to the metal substrate. The second patterned circuit layer partially exposes the second dielectric layer.

In an embodiment of the disclosure, the substrate structure further includes a solder mask layer disposed on the second patterned circuit layer. The solder mask layer has a plurality of solder mask openings, and the solder mask openings partially expose the second patterned circuit layer.

In an embodiment of the disclosure, the metal substrate, the first patterned circuit layer, and the second patterned circuit layer define a plurality of conductive pillars.

In an embodiment of the disclosure, the substrate structure further includes a filling material configured to cover the second dielectric layer exposed from the second patterned circuit layer, and the filling material is aligned with the second patterned circuit layer.

In an embodiment of the disclosure, the at least one second dielectric layer includes two second dielectric layers, and the at least one second patterned circuit layer includes two second patterned circuit layers. The second dielectric layer and the second patterned circuit layer are alternately stacked on the second surface of the metal substrate, and the filling material is disposed between the second dielectric layers.

In an embodiment of the disclosure, the substrate structure further includes a filling material configured to cover the first dielectric layer exposed from the first patterned circuit layer, and the filling material is aligned with the first patterned circuit layer.

In an embodiment of the disclosure, the at least one first dielectric layer includes two first dielectric layers, and the at least one first patterned circuit layer includes two first patterned circuit layers. The first dielectric layers and the first patterned circuit layers are alternately stacked on the first surface of the metal substrate, and the filling material is disposed between the first dielectric layers.

Based on the above, in the design of the substrate structure of the disclosure, the metal substrate is adopted as the base, and the through holes of the metal substrate are filled with insulating material. Furthermore, the dielectric layer made of aluminum nitride or silicon carbide is disposed on the metal substrate, and the patterned circuit layer is disposed on the dielectric layer and configured to fill the openings of the dielectric layer and be connected to the metal substrate. Compared with the related art in which packaging substrates are formed by using an organic resin impregnated fiberglass cloth as the core board and a pure resin material (such as an ABF) or a resin impregnated fiberglass cloth (prepreg) as the build-up material, the substrate structure of the disclosure has lesser thickness and better heat dissipation effect and meets the thinning trend.

To make the features and advantages of the disclosure more comprehensible, embodiments are described in detail with the drawings as follows.

### BRIEF DESCRIPTION OF THE DRAWING

FIG. 1 is a schematic cross-sectional view of a substrate structure according to an embodiment of the disclosure.

FIG. 2 is a schematic cross-sectional view of a substrate structure according to another embodiment of the disclosure.

### DESCRIPTION OF THE EMBODIMENTS

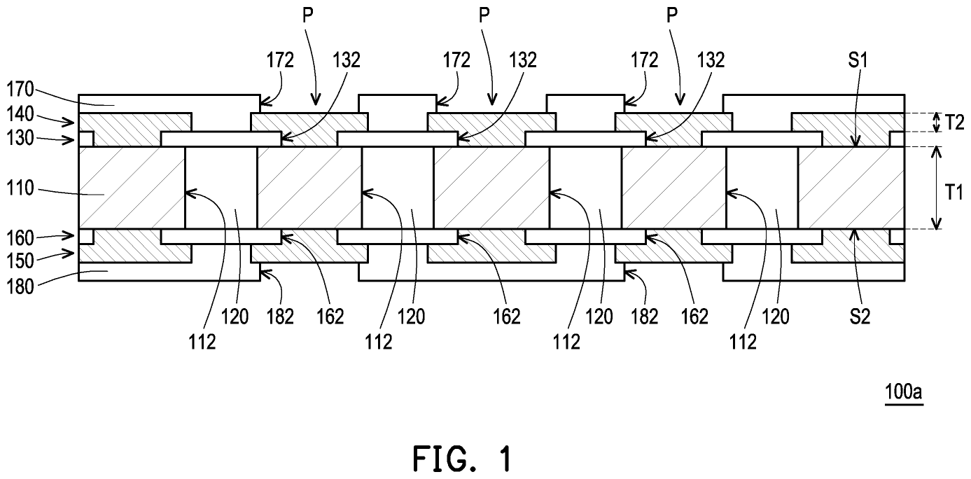

FIG. 1 is a schematic cross-sectional view of a substrate structure according to an embodiment of the disclosure. As shown in FIG. 1, in this embodiment, the substrate structure 100a includes a metal substrate 110, an insulating material 120, at least one first dielectric layer 130 (one layer is schematically shown), and at least one first patterned circuit layer 140 (one layer is schematically shown). The metal substrate 110 has a first surface S1 and a second surface S2 opposite to each other and a plurality of through holes 112 penetrating the metal substrate 110 and connecting the first surface S1 and the second surface S2. The insulating material 120 fills the through holes 112 and is aligned with the first surface S1 and the second surface S2. The first dielectric layer 130 is disposed on the first surface S1 of the metal substrate 110 and the insulating material 120 and has a plurality of first openings 132. The first openings 132 partially expose the metal substrate 110. The material of the first dielectric layer 130 is, for example, aluminum nitride or silicon carbide. The first patterned circuit layer 140 is disposed on the first dielectric layer 130 and is configured to fill the first openings 132 and be connected to the metal substrate 110.

In this embodiment, the metal substrate 110 is, for example, a copper substrate, but the disclosure is not limited thereto. The through hole 112 of the metal substrate 110 has, for example, a fixed diameter, and the first dielectric layer 130 completely covers one end of the through holes 112 and partially exposes the metal substrate 110. The first patterned circuit layer 140 fills the first openings 132 and extends to the first dielectric layer 130. The first patterned circuit layer 140 is structurally and electrically connected to the metal substrate 110, and the first patterned circuit layer 140 partially exposes the first dielectric layer 130. In one embodiment, the thickness T1 of the metal substrate 110 is, for example, between 1 μm and 5 μm, and the thickness T2 of the first patterned circuit layer is, for example, between 1 μm and 3 μm, but the disclosure is not limited thereto.

As shown in FIG. 1, the substrate structure 100 of this embodiment further includes at least one second dielectric layer 160 (one layer is schematically shown). The second dielectric layer 160 is directly disposed on the second surface S2 of the metal substrate 110 and the insulating material 120, and the second dielectric layer 160 completely covers the other end of the through holes 112 and partially exposes the metal substrate 110. The second dielectric layer 160 has a plurality of second openings 162, and the second openings 162 partially expose the metal substrate 110. And the material of the second dielectric layer 160 is, for example, aluminum nitride or silicon carbide.

Furthermore, the substrate structure 100 of the present embodiment further includes at least one second patterned circuit layer 150 (one layer is schematically shown) disposed on the second dielectric layer 160 and configured to fill the second openings 162 and be connected to the metal substrate 110. The second patterned circuit layer 150 fills the second openings 162 and extends to the second dielectric layer 160. The second patterned circuit layer 150 is structurally and electrically connected to the metal substrate 110, and part of the second dielectric layer 160 is exposed from the second patterned circuit layer 150. And the metal substrate 110, the first patterned circuit layer 140, and the second patterned circuit layer 150 define a plurality of conductive pillars P that are separated from one another.

In addition, the substrate structure 100 of this embodiment further includes a solder mask layer 170 disposed on the first patterned circuit layer 140. The solder mask layer 170 has a plurality of solder mask openings 172, and the solder mask openings 172 partially expose the first patterned circuit layer 140, which may be adopted as pads later. The substrate structure 100 further includes a solder mask layer 180 disposed on the second patterned circuit layer 150. The solder mask layer 180 has a plurality of solder mask openings 182, and the solder mask openings 182 partially expose the second patterned circuit layer 150, which may be adopted as pads later. Here, the substrate structure 100a is embodied as a single-layer, double-sided circuit board structure.

In terms of manufacturing, the material of the metal substrate 110 in this embodiment is, for example, copper, which means that copper is used as the core substrate, and the through holes 112 are formed by etching. The etched metal substrate 110 forms a plurality of copper pillars separated from one another, which replace the conventional process of mechanically or laser drilling the core layer and then form upper and lower via structures by electroplating techniques. Next, an organic resin is used as the insulating material 120 to fill the through-holes 112, and the insulating material 120 is aligned with the first surface S1 and the second surface S2 of the metal substrate 110 by grinding to achieve a planarized surface. After that, the first dielectric layer 130 and the second dielectric layer 160 made of aluminum nitride or silicon carbide are formed on the metal substrate 110 by sputtering to serve as interlayer insulating layers. As a sputtering process is adopted instead of the conventional build-up techniques, the first dielectric layer 130 and the second dielectric layer 160 are able to have lesser thicknesses. Next, the first openings 132 and the second openings 162 are formed to act as channels for interlayer vias by using laser, which means that the first openings 132 and the second openings 162 are respectively laser openings. After that, an electroplating seed layer is formed by sputtering or chemical deposition, and a conductive material is electroplated and patterned by the electroplating seed layer to form the first patterned circuit layer 140 and the second patterned circuit layer 150. Finally, the solder mask layer 170 and the solder mask layer 180 are respectively formed on the first patterned circuit layer 140 and the second patterned circuit layer 150. The fabrication of the substrate structure 100 with a lesser thickness is completed so far.

Compared with the related art in which packaging substrates are formed by using an organic resin impregnated fiberglass cloth as the core board and a pure resin material (such as an ABF) or a resin impregnated fiberglass cloth (prepreg) as the build-up material, as the metal substrate 110 in this embodiment is used as the base and the first dielectric layer 130 made of aluminum nitride or silicon carbide is used as the build-up material, the substrate structure 100a of this embodiment has lesser thickness and better heat dissipation effect and meets the thinning trend.

Note here that the following embodiments adopt the reference numbers and part of the contents from the previous embodiments. As the same reference numbers represent the same or similar elements, the same technical contents are hereby omitted. Reference may be made to the foregoing embodiments for the description omitted. The same descriptions will not be repeated hereinafter.

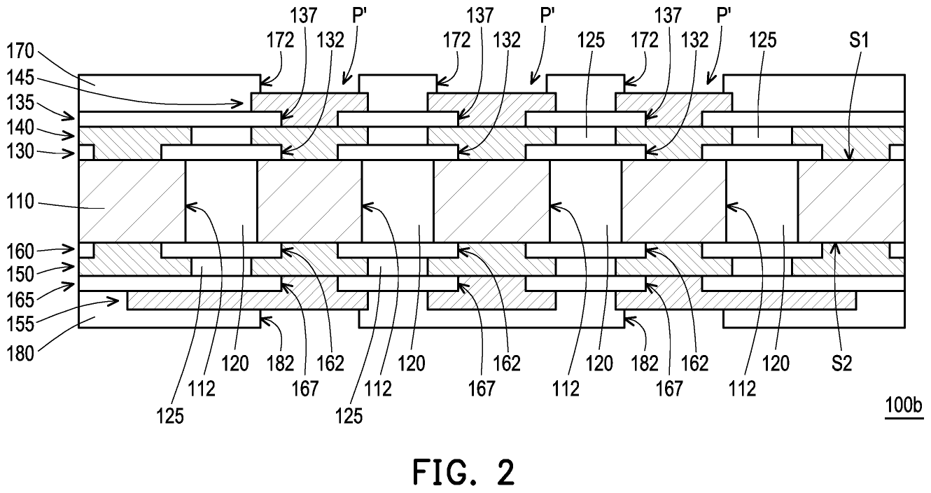

FIG. 2 is a schematic cross-sectional view of a substrate structure according to another embodiment of the disclosure. As shown in FIG. 1 and FIG. 2, the substrate structure 100b of this embodiment is similar to the substrate structure 100a. The differences between the two are that the substrate structure 100b of this embodiment further includes a filling material 125 covering the first dielectric layer 130 exposed from the first patterned circuit layer 140, and that the filling material 125 is aligned with the first patterned circuit layer 140 to form a flat surface. The process is followed by forming a first dielectric layer 135 made of aluminum nitride or silicon carbide on the flat surface by sputtering to serve as an interlayer insulating layer. A first opening 137 is then formed as a channel for the interlayer via by using laser. After that, an electroplating seed layer is formed by sputtering or chemical deposition, and a conductive material is electroplated using the electroplating seed layer and is patterned to form a first patterned circuit layer 145. In other words, this embodiment includes two first dielectric layers 130 and 135 and two first patterned circuit layers 140 and 145 on the first surface S1 of the metal substrate 110. The first dielectric layers 130 and 135 and the first patterned circuit layers 140 and 145 are alternately stacked on the first surface S1 of the metal substrate 110, and the filling material 125 is disposed between the first dielectric layers 130 and 135. The first dielectric layer 135 is disposed between the first patterned circuit layer 140 and the first patterned circuit layer 145, and has a first opening 137. The first patterned circuit layer 145 fills the first opening 137 and is connected to the first patterned circuit layer 140.

Similarly, on the second surface S2 of the metal substrate 110, the substrate structure 100b further includes a filling material 125 covering the second dielectric layer 160 exposed from the second patterned circuit layer 150. The filling material 125 is aligned with the second patterned circuit layer 150 to form a flat surface. In addition, the substrate structure 100b further includes a second dielectric layer 165 and a second patterned circuit layer 155. The second dielectric layer 165 is disposed between the second patterned circuit layer 150 and the second patterned circuit layer 155, and has a plurality of second openings 167. The second patterned circuit layer 155 fills the second opening 167 and is connected to the second patterned circuit layer 150. In other words, this embodiment includes two second dielectric layers 160 and 165 and two second patterned circuit layers 150 and 155 on the second surface S2 of the metal substrate 110. The second dielectric layers 160 and 165 and the second patterned circuit layers 150 and 155 are alternately stacked on the second surface S2 of the metal substrate 110, and the filling material 125 is disposed between the second dielectric layers 160 and 165.

Moreover, the solder mask layer 170 is disposed on the first patterned circuit layer 145, and a plurality of solder mask openings 172 partially expose the first patterned circuit layer 145, which may be adopted as pads later. The solder mask layer 180 is disposed on the second patterned circuit layer 155, and the solder mask openings 182 partially expose the second patterned circuit layer 155, which may also be adopted as pads later. And the metal substrate 110, the first patterned circuit layer 140, the first patterned circuit layer 145, the second patterned circuit layer 150, and the second patterned circuit layer 155 define a plurality of conductive pillars P′. Here, the substrate structure 100b is embodied as a multilayer double-sided circuit board structure.

To sum up, in the design of the substrate structure of the disclosure, the metal substrate is adopted as the base, and the through holes of the metal substrate are filled with insulating material. Furthermore, the dielectric layer made of aluminum nitride or silicon carbide is disposed on the metal substrate, and the patterned circuit layer is disposed on the dielectric layer and configured to fill the openings of the dielectric layer and be connected to the metal substrate. Compared with the related art in which packaging substrates are formed by using organic resin impregnated fiberglass cloth as the core board and pure resin material (such as an ABF) or a resin impregnated fiberglass cloth (prepreg) as the build-up material, the substrate structure of the disclosure has lesser thickness and better heat dissipation effect and meets the thinning trend.

Although the disclosure has been disclosed by the embodiments above, they are not intended to limit the disclosure. Anyone with ordinary knowledge in the art can make changes and modifications without departing from the spirit and scope of the disclosure. Therefore, the protection scope of the disclosure shall be determined by the scope of the claims attached.

What is claimed is:

1. A substrate structure, comprising:
a metal substrate having a first surface and a second surface opposite to each other and a plurality of through holes penetrating the metal substrate and connecting the first surface and the second surface;
an insulating material configured to fill the through holes and be aligned with the first surface and the second surface;
at least one first dielectric layer disposed on the first surface of the metal substrate and the insulating material and having a plurality of first openings, wherein the first openings partially expose the metal substrate, and a material of the at least one first dielectric layer comprises aluminum nitride or silicon carbide; and
at least one first patterned circuit layer disposed on the at least one first dielectric layer and configured to fill the first openings and be connected to the metal substrate, wherein the at least one first patterned circuit layer partially exposes the at least one first dielectric layer.

2. The substrate structure according to claim 1, further comprising:
a solder mask layer disposed on the at least one first patterned circuit layer and having a plurality of solder mask openings that partially expose the at least one first patterned circuit layer.

3. The substrate structure according to claim 1, further comprising:
at least one second dielectric layer disposed on the second surface of the metal substrate and the insulating material and having a plurality of second openings that partially expose the metal substrate, wherein a material of the at least one second dielectric layer comprises aluminum nitride or silicon carbide.

4. The substrate structure according to claim 3, further comprising:
at least one second patterned circuit layer disposed on the at least one second dielectric layer and configured to fill the second openings and be connected to the metal substrate, wherein the at least one second patterned circuit layer partially exposes the at least one second dielectric layer.

5. The substrate structure according to claim 4, further comprising:
a solder mask layer disposed on the at least one second patterned circuit layer and having a plurality of solder mask openings that partially expose the at least one second patterned circuit layer.

6. The substrate structure according to claim 4, wherein the metal substrate, the at least one first patterned circuit layer, and the at least one second patterned circuit layer define a plurality of conductive pillars.

7. The substrate structure according to claim 4, further comprising:
a filling material configured to cover the at least one second dielectric layer exposed from the at least one second patterned circuit layer, wherein the filling material is aligned with the at least one second patterned circuit layer.

8. The substrate structure according to claim 7, wherein the at least one second dielectric layer comprises two second dielectric layers, the at least one second patterned circuit layer comprises two second patterned circuit layers, the second dielectric layers and the second patterned circuit layers are alternately stacked on the second surface of the metal substrate, and the filling material is disposed between the second dielectric layers.

9. The substrate structure according to claim 1, further comprising:
a filling material configured to cover the at least one first dielectric layer exposed from the at least one first patterned circuit layer, wherein the filling material is aligned with the at least one first patterned circuit layer.

10. The substrate structure according to claim 9, wherein the at least one first dielectric layer comprises two first dielectric layers, the at least one first patterned circuit layer comprises two first patterned circuit layers, the first dielectric layers and the first patterned circuit layers are alternately stacked on the first surface of the metal substrate, and the filling material is disposed between the first dielectric layers.
